(19) United States
(12) Patent Application Publication
(10) Pub. No.: US 2002/0074544 A1
(43) Pub. Date: Jun. 20, 2002

(54) Ramp-edge josephson junction devices and methods for fabricating the same

(76) Inventors: Gun Yong Sung, City of Taejon (KR); Chi Hong Choi, City of Pusan (KR); Kwang Yong Kang, City of Sacheon (KR)

Correspondence Address: SEED INTELLECTUAL PROPERTY LAW GROUP PLLC, 701 FIFTH AVE, SUITE 6300, SEATTLE, WA, 98104-7092, US

(21) Appl. No.: 09/741,955

(22) Filed: Dec. 19, 2000

(30) Foreign Application Priority Data
Dec. 21, 1999 (KR) 1999-59975

(51) Int. Cl. H01L 39/22; H01L 31/0256; H01L 29/06

(52) U.S. Cl. 257/31

(57) ABSTRACT

The invention relates generally to high-temperature superconducting Josephson junction devices necessary in implementing an advanced a single flux quantum circuit for a digital electronic device using superconductors. More particularly, the invention relates to ramp-edge Josephson junction devices and methods for fabricating the same, using copper-series oxide super-conducting thin films. According to the present invention, the ramp-edge Josephson junction device comprises a substrate, a first electrode layer having a ramp-edge and a first insulating layer formed on the substrate sequentially, a transformation layer formed at the ramp-edge of the first electrode layer by illumination of excimer laser and by annealing process, and a second electrode layer and a second electrode layer and a second insulating layer formed on the first electrode layer including the transformation layer and the first insulating layer sequentially.

### TECHNICAL FIELD

The invention relates generally to high-temperature superconducting Josephson junction devices necessary in implementing an advanced single flux quantum circuit for a digital electronic device using superconducting. More particularly, the invention relates to ramp-edge Josephson junction devices and methods for fabricating the same, using copper oxide superconducting thin films.

### BACKGROUND OF THE INVENTION

In order to fabricate ramp-edge junction, it is recommended that barrier materials are employed which are very low in a contact resistance with superconductors, does not react chemically and give a base on which super-conductors can be epitaxially grown. It is difficult to control major factors for fabricating the junction such as a barrier thickness, edge, angle, interface structure of a junction edge face, uniformity, ion beam etch, etc. Due to this, its fabrication becomes complicate and uniformity and reappearance are degraded even many research has been made.

As these barrier materials are used, there are problems such as control of the superconductor/barrier layer interface, control of electrical, structural characteristic in the barrier layer interface, etc. In particular, as growth of a thin film is not uniform at high temperature, deposition process is not suitable for fabricating a thin uniform barrier for a superconducting junction. Therefore, there is a need for a new type of a technology for fabricating a barrier layer in order to improve uniformity of a super-conducting Josephson junction.

In this view, a study on ramp-edge junctions, using an artificial barrier that is different in structural and electrical characteristic, without using barrier materials, has been actively made in several working groups. The method of fabricating the artificial barrier involves an interface-engineered junction method using a vacuum annealing process and a RF plasma process instead of the process of depositing a barrier layer, which was published in the paper entitled “Properties of Interface-engineered high Tc Josephson Junctions” by B. H. Moeckly and K. Char, Applied Physics Letters, Vol. 71, pp.2526˜2528.

Also, another method involves a hot ion damage process using ion beam damage after the temperature is step up, and a controlled interfacial disorder process of chemically processing a lower electrode edge, wherein the controlled interfacial disorder process is published in the paper “IEEE Trans. on Appl. Supercond” by Brian D. Hunt, et al., Vol. 9, No.2, pp. 3362˜3365 (1999). Also, still another method involves a process by an artificial barrier layer is made by ion beams, using LaSrAlTaO₆ (LSAT) being insulating materials, which are similar in YBCO, a lattice constant and a coefficient of thermal coefficient, and has a relatively low dielectric constant, as an insulating layer and a substrate. This process was published in the paper “IEEE Trans. on Appl. Supercond” by T. Satoh, et al., Vol. 9, No. 2, pp. 3141˜3144 (1999).

However, the conventional RF plasma process is performed within a thin film deposition chamber. Thus, there is a problem that deposition materials adhered to the internal wall of the chamber contaminates the ramp-edge surface upon plasma is generated. Also, there is a problem that materials etched by ion beam are again deposited the ramp-edge during ion beam process. Further, the greatest problem in fabricating super-conducting Josephson junctions is that the standard variations in the junction characteristic value are too great. In order to lower the variations, it is required that the process of fabricating the junction be simplified and parameters in the process be minimized.

### SUMMARY OF THE INVENTION

The present invention is therefore contrived to solve the conventional problems and an object of the present invention to provide ramp-edge Josephson junction devices and methods for fabricating the same, which has a high reproducibility through simplified process in high-temperature superconducting Josephson junction devices used in an ultra-high digital and ultra-frequency information communication device.

In order to accomplish the object, a ramp-edge Josephson junction device according to one aspect of the present invention is provided to include a substrate, a first electrode layer having a ramp-edge and a first insulating layer formed on the substrate sequentially, a transformation layer formed at the ramp-edge of the first electrode layer by illumination of excimer laser and by annealing process, and a second electrode layer and a second insulating layer formed on the first electrode layer including the transformation layer and the first insulating layer, sequentially.

Preferably, the first and second electrode layers are copper oxide superconductor, and the copper oxide superconductor is selected from a group consisting of Bi₂Sr₂CaₙCuₙ₊₁O₂ₙ₊₆, Bi₂Ba₂CaₙCuₙ₊₁O₂ₙ₊₆, Tl₂Sr₂CaₙCuₙ₊₁O₂ₙ₊₆, Tl₂Ba₂CaₙCuₙ₊₁O₂ₙ₊₆ (n is a fixed number from 0 to 4) or YBa₂Cu₃O₇₋ₓ, NdBa₂Cu₃O₇₋ₓ, SmBa₂Cu₃O₇₋ₓ, ErBa₂Cu₃O₇₋ₓ, GdBa₂Cu₃O₇₋ₓ, DyBa₂Cu₃O₇₋ₓ, HoBa₂Cu₃O₇₋ₓ, TmBa₂Cu₃O₇₋ₓ, LuBa₂Cu₃O₇₋ₓ, LnBa₂Cu₃O₇₋ₓ (x is 0 to 0.5).

Preferably, the first insulating layer and said second insulating layer are perovskite-type oxide, and the perovskite-type oxide is selected from a group consisting of SrTiO₃, LaAlO₃, Sr₂AlTaO₆, Sr₂AlNbO₆ or BaTbO₃.

More preferably, the inclination angle of the ramp-edge in said first electrode layer is formed to be below about 20°.

Also, it is preferred that the junction device further comprise electrode pads each connected said first electrode layer and said second electrode layer.

Further, a method of fabricating a ramp-edge Josephson junction device according to one aspect of the present invention is provided. The method includes the following steps. A first step is of sequentially forming a first electrode layer having a ramp edge, and a first insulating layer on a substrate. A second step is of illuminating the ramp-edge of the first electrode layer with an excimer laser and performing an annealing process to form a transformation. And a third step is of sequentially forming a second electrode layer and a second insulating layer on the first electrode layer including the transformation layer, and the first insulating layer.

Preferably, in the second step, the energy density of the excimer laser illuminated is about 0.3˜1.2 J/cm².

Preferably, in the second step, the excimer laser uses one of ArF, KrF and XeCl the wavelengths of which are 193 nm, 248 nm and 308 nm, respectively.

Preferably, in the second step, the annealing process is performed at the temperature of about 500˜600° C. under the pressure of oxygen for one hour.

More preferably, the first and second electrode layers, and the first and second insulating layers are formed by pulsed laser deposition method using an excimer laser.

In addition, in the fist step, the step of forming the ramp-edge further includes sequentially forming a first electrode and a first insulating layer on a substrate, forming a photoresist pattern on the first insulating layer by photolithography, and etching slantingly the first insulating layer by ion beam using the photoresist pattern as a mask, and slantingly etching the first electrode layer by ion beams using the first insulating layer slantingly etched as a mask.

More preferably, the method further includes a step of forming electrode pads each connected the first electrode layer and the second electrode layer.

### BRIEF DESCRIPTION OF THE DRAWINGS

The aforementioned aspects and other features of the present invention will be explained in the following description, taken in conjunction with the accompanying drawings, wherein:

FIG. 1 through FIG. 6 are flowchart showing a method of fabricating high-temperature superconducting ramp-edge Josephson junction device according to one embodiment of the present invention.

### DETAILED DESCRIPTION OF THE INVENTION

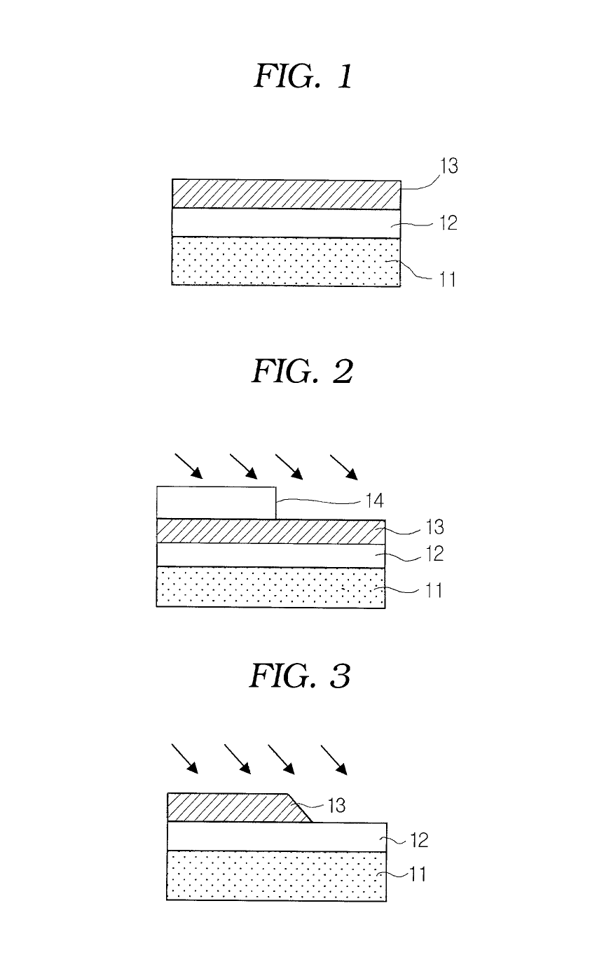

A method of fabricating ramp-edge Josephson junction devices according to one embodiment of the present invention will be now explained in detail by reference to FIGS. 1 to 6.

First, a first electrode layer 12 and a first insulating layer 13, both of which are superconductor, are sequentially formed on a single crystal substrate 11, as shown in FIG. 1. It is preferred that the single crystal substrate 11 is a LaAlO₃ (LAO) single crystal substrate, and the first electrode layer 12 is copper oxide high-temperature superconductor, which may be formed of one of Bi₂Sr₂Caₙ,Cuₙ₊₁O₂ₙ₊₆, Bi₂Ba₂CaₙCuₙ₊₁O₂ₙ₊₆, Tl₂Sr₂CaₙCuₙ₊₁O₂ₙ₊₆, Tl₂Ba₂CaₙCuₙ₊₁O₂ₙ₊₆ (n is a fixed number from 0 to 4) or YBa₂Cu₃O₇₋ₓ, NdBa₂Cu₃O₇₋ₓ, SmBa₂Cu₃O₇₋ₓ, ErBa₂Cu₃O₇₋ₓ, GdBa₂Cu₃O₇₋ₓ, DyBa₂Cu₃O₇₋ₓ, HoBa₂Cu₃O₇₋ₓ, TmBa₂Cu₃O₇₋ₓ, LuBa₂Cu₃O₇₋ₓ, LnBa₂Cu₃O₇₋ₓ (x is 0 to 0.5).

Also, the first insulating layer 13 is a perovskite-type oxide, which may includes SrTiO₃, LaAlO₃, Sr₂AlTaO₆, Sr₂AlNbO₆ or BaTbO₃. The single crystal substrate 11 may be also formed of perovskite-type oxide. It is preferred that the first electrode layer and the first insulating layer are about 100˜200 nm in thickness.

The first electrode layer 12 and the first insulating layer 13 may be formed by pulsed laser deposition method using excimer layer. At this time, the laser may use one of ArF, KrF and XeCl the wavelengths of which are 193 nm, 248 nm and 308 nm, respectively.

Next, a photoresist pattern 14 is formed on a given region of the first insulating layer 13 by photolithography process, as shown in FIG. 2. Then, ion beam etching is performed using the photoresist pattern 14 as a mask. That is, the incident angle of the illuminated ion beam is maintained at about 30˜45° and the first insulating layer 13 is slantingly etched while a sample is rotated. At this time, it is preferred that the voltage of the ion beam is in the range of about 200˜450V and its current density is about 1.0˜2.0 mA/cm². The type of the ion beam may include argon (Ar).

Thereafter, as shown in FIG. 3, the remaining photoresist pattern 14 is removed. Then, the first electrode layer 12 is etched by ion beam etch method, using the first insulating layer 13 slantingly etched as an etch mask. It is preferred that the inclination angle of the ramp-edge 15 of the first electrode layer etched thus, is below about 20°. The type of the ion beam for the ion beam etching may include argon (Ar).

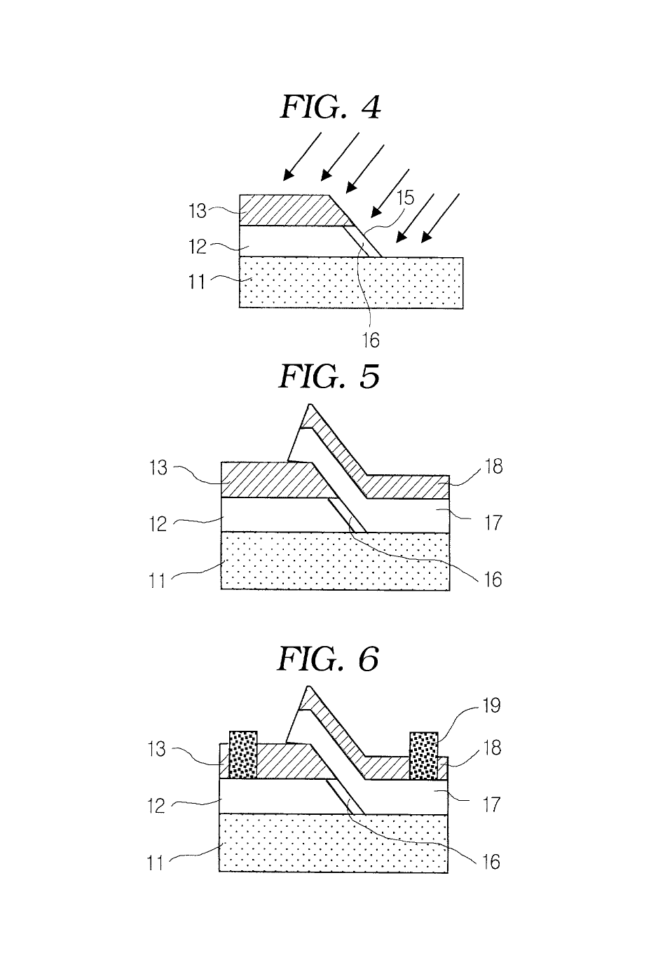

Next, as shown in FIG. 4, the sample is transferred to the pulse laser deposition apparatus. Then, the surface of the etched ramp-edge surface is illuminated with an excimer laser to transform the crystal phase of the surface layer. More particularly, the etched ramp-edge surface is illuminated by an excimer laser having the energy density of about 0.3˜1.2 J/cm² under the pressure of oxygen having about 100˜500 mTorr for about one hour, thus transforming the crystal phase of the surface layer. Then, an annealing process is performed at the temperature of about 500˜600° C. under the pressure of oxygen having 100˜500 mTorr, thus forming a transformation layer 16 having a physically and chemically stabilized state on the ramp-edge surface layer. Meanwhile, the excimer laser may use one of ArF, KrF and XeCl the wavelengths of which are 193 nm, 248 nm and 308 nm, respectively.

Then, as shown in FIG. 5, a second electrode layer 17 and a second insulating layer 18 are sequentially formed on the resulting surface. At this time, the second electrode layer 17 and a second insulating layer 18 are formed by the same pulse laser deposition method to the method of forming the first electrode layer and the first insulating layer. It is preferred that the thickness of the second electrode layer is about 100˜200 nm and that of the second insulating layer is about 30˜100 nm. Also, the materials of the second electrode layer 17 and the second insulating layer 18 may use the materials for the first electrode layer and the first insulating layer. Next, with the same condition explained by reference to FIG. 2 and FIG. 3, a photoresist pattern (not shown) is formed on a given region of the second insulating layer 18 by photolithography process. Then, the second insulating layer 1 and the second electrode layer 17 are slantingly etched by ion beam etching method. Also, as shown in FIG. 6, in order to avoid an electrical contact with a measuring terminal, given regions corresponding to electrode pads of the first electrode pad 12 and the second electrode layers 17 are exposed by photolithography process. Next, a metal electrode 19 is formed. Explaining particularly, a photoresist pattern (not shown) is formed on the first and second insulating layers except for the regions in which the electrode pads are to be formed. Then, the insulating layers are chemically etched with 1% HF aqueous solution to expose the electrode pads. Thus, after a metal layer, for example, made of gold (Au), is deposited, the remaining metal layer is removed by lift-off method, thus completing electrode pads. Additionally, in order to compensate for the damage by ion beam etching, an additional annealing process may be performed.

As mentioned above, the present invention can prevent contaminating the ramp-edge surface of the high-temperature super-conducting first electrode layer by organic materials when photoresist is removed since an insulating layer formed on the electrode layer of a super-conductor is used as an ion beam etch mask. Also, the present invention can obtain an uniform, reappearing and stable Josephson junction device since a ramp-edge surface is illuminated with an excimer laser to form a transformation layer and is then stabilized by a subsequent annealing process

Additionally, the present invention can fabricate a high-temperature super-conducting ramp-edge junction with simplified process, compared a conventional method of forming a barrier layer that is artificially formed, or a transformation layer using ion beam or RF plasma.

The present invention has been described with reference to a particular embodiment in connection with a particular application. Those having ordinary skill in the art and access to the teachings of the present invention will recognize additional modifications and applications within the scope thereof.

It is therefore intended by the appended claims to cover any and all such applications, modifications, and embodiments within the scope of the present invention.

What is claimed is:

1. A ramp-edge Josephson junction device, comprising:
a substrate;
a first electrode layer having a ramp-edge and a first insulating layer formed on said substrate sequentially;
a transformation layer formed at the ramp-edge of the first electrode layer by illumination of excimer laser and by annealing process; and
a second electrode layer and a second insulating layer formed on said first electrode layer including said transformation layer and said first insulating layer sequentially.

2. The ramp-edge Josephson junction device according to claim 1, wherein said first and second electrode layers are copper-series oxide superconductor.

3. The ramp-edge Josephson junction device according to claim 2, wherein said copper-series oxide superconductor is selected from a group consisting of Bi₂Sr₂CaₙCuₙ₊₁O₂ₙ₊₆, Bi₂Ba₂CaₙCuₙ₊₁O₂ₙ₊₆, Tl₂Sr₂CaₙCuₙ₊₁O₂ₙ₊₆, Tl₂Ba₂CaₙCuₙ₊₁O₂ₙ₊₆ ( is a fixed number from 0 to 4) or YBa₂Cu₃O₇₋ₓ, NtBa₂Cu₃O₇₋ₓ, SmBa₂Cu₃O₇₋ₓ, ErBa₂Cu₃O₇₋ₓ, GdBa₂Cu₃O₇₋ₓ, DyBa₂Cu₃O₇₋ₓ, HoBa₂Cu₃O₇₋ₓ, TmBa₂Cu₃O₇₋ₓ, LuBa₂Cu₃O₇₋ₓ, LnBa₂Cu₃O₇₋ₓ (x is 0 to 0.5).

4. The ramp-edge Josephson junction device according to claim 1, wherein said first insulating layer and said second insulating layer are perovskite-type oxide.

5. The ramp-edge Josephson junction device according to claim 4, wherein said perovskite-type oxide is selected from a group consisting of SrTiO₃, LaAlO₃, Sr₂AlTaO₆, Sr₂AlNbO₆ or BaTbO₃.

6. The ramp-edge Josephson junction device according to claim 1, wherein an inclination angle of said ramp-edge in said first electrode layer is formed to be below about 20°.

7. The ramp-edge Josephson junction device according to claim 1, further comprising electrode pads each connected said first electrode layer and said second electrode layer.

8. A method of fabricating a ramp-edge Josephson junction device, comprising:
a first step of sequentially forming a first electrode layer having a ramp edge, and a first insulating layer on a substrate;
a second step of illuminating sad ramp-edge of the first electrode layer with an excimer laser and performing an annealing process to form a transformation layer; and
a third step of sequentially forming a second electrode layer and a second insulating layer on said first electrode layer including said transformation layer and said first insulating layer.

9. The method of fabricating a ramp-edge Josephson junction device according to claim 8, wherein in said second step, the energy density of the excimer laser illuminated is about 0.3˜1.2 J/cm².

10. The method of fabricating a ramp-edge Josephson junction device according to claim 8, wherein in said second step, said excimer laser uses one of ArF, KrF and XeCl the wave lengths of which are 193 nm, 248 nm and 308 nm, respectively.

11. The method of fabricating a ramp-edge Josephson junction device according to claim 8, wherein in said second step, said annealing process is performed at a temperature of about 500˜600° C. under the pressure of oxygen for one hour.

12. The method of fabricating a ramp-edge Josephson junction device according to claim 8, wherein said first and second electrode layers are formed of copper-series oxide superconductor.

13. The method of fabricating a ramp-edge Josephson junction device according to claim 12, wherein said copper-series oxide superconductor is selected from a group consisting of Bi₂Sr₂CaₙCuₙ₊₁O₂ₙ₊₆, Bi₂Ba₂CaₙCuₙ₊₁O₂ₙ₊₆, Tl₂Sr₂CaₙCuₙ₊₁O₂ₙ₊₆, Tl₂Ba₂CaₙCuₙ₊₁O₂ₙ₊₆ (n is a fixed number from 0 to 4) or YBa₂Cu₃O₇₋ₓ, NdBa₂Cu₃O₇₋ₓ, SmBa₂Cu₃O₇₋ₓ, ErBa₂Cu₃O₇₋ₓ, GdBa₂Cu₃O₇₋ₓ, DyBa₂Cu₃O₇₋ₓ, HoBa₂Cu₃O₇₋ₓ, TmBa₂Cu₃O₇₋ₓ, LuBa₂Cu₃O₇₋ₓ, LnBa₂Cu₃O₇₋ₓ (x is 0 to 0.5).

14. The method of fabricating a ramp-edge Josephson junction device according to claim 8, wherein said first insulating layer and said second insulating layer are formed of perovskite-type oxide.

15. The method of fabricating a ramp-edge Josephson junction device according to claim 14, wherein said perovskite-type oxide is selected from a group consisting of SrTiO₃, LaAlO₃, Sr₂AITaO₆, Sr₂AlNbO₆ or BaTbO₃.

16. The method of fabricating a ramp-edge Josephson junction device according to claim 8, wherein said first and second electrode layers, and said first and second insulating layers are formed by pulsed laser deposition method using an excimer laser.

17. The method of fabricating a ramp-edge Josephson junction device according to claim 8, wherein in said first step, the step of forming the ramp-edge further comprises:
sequentially forming a first electrode an d a first insulating layer on a substrate;
forming a photoresist pattern on said first insulating layer by photolithography, and etching slantingly said first insulating layer by ion beam using said photoresist pattern as a mask; and
slantingly etching said first electrode layer by ion beams using said first insulating layer slantingly etched as a mask.

18. The method of fabricating a ramp-edge Josephson junction device according to claim 17, wherein said an inclination angle of said ramp-edge in said first electrode layer is formed to be below about 20°.

19. The method of fabricating a ramp-edge Josephson junction device according to claim 8, further comprising a step of forming electrode pads each connected said first electrode layer and said second electrode layer.
